(19) United States
(12) Patent Application Publication
(10) Pub. No.: US 2024/0217057 A1
(43) Pub. Date: Jul. 4, 2024

(54) CHEMICAL MECHANICAL POLISHING APPARATUS AND METHOD OF REPLACING POLISHING PAD USING THE SAME

(71) Applicant: Samsung Electronics Co., Ltd., Suwon-si (KR)

(72) Inventors: Donghoon Kwon, Suwon-si (KR); Chungki Min, Suwon-si (KR)

(21) Appl. No.: 18/347,707

(22) Filed: Jul. 6, 2023

(30) Foreign Application Priority Data
Dec. 30, 2022 (KR) 10-2022-0191238

(51) Int. Cl. B24B 37/26

(52) U.S. Cl. CPC B24B 37/26

(57) ABSTRACT

The present disclosure relates to a chemical mechanical polishing apparatus and a method of replacing a polishing pad using the same. The chemical mechanical polishing apparatus includes: a polishing table; a polishing pad attachment feature on a surface of the polishing table; a polishing pad supply area outside the polishing table; and a polishing pad carrier configured to move a polishing pad from the polishing pad supply area to the polishing pad attachment feature, wherein the polishing pad attachment feature includes a magnetic feature and/or an adsorption feature to attach the polishing pad to the polishing table.

### CROSS-REFERENCE TO RELATED APPLICATION

This application claims priority to and the benefit of Korean Patent Application No. 10-2022-0191238 filed in the Korean Intellectual Property Office on Dec. 30, 2022, the entire contents of which are incorporated herein by reference.

### BACKGROUND

The present disclosure relates to a chemical mechanical polishing apparatus and a method of replacing a polishing pad using the same.

In general, a chemical mechanical polishing (CMP) process is a standard process of polishing a surface of a wafer, such as a wafer having a polishing layer for fabricating a semiconductor, by rotating the wafer relative to a polishing table.

At this time, a polishing pad made of a polytex material, by which the wafer is polished, may be used in the polishing table. The polishing pad is worn out during the polishing process, and should be replaced when it is worn out at a predetermined level.

It is typical for polishing pad replacement work that an engineer directly attaches and detaches the polishing pad, which causes problems such as manpower cost, replacement time, and poor attachment after replacement.

The above information disclosed in this Background section is only for enhancement of understanding of the background of the described technology, and therefore it may contain information that does not form prior art that is already known to a person of ordinary skill in the art.

### SUMMARY

The present disclosure provides a polishing apparatus and a method of replacing a polishing pad having the advantages of reducing variables and reducing process costs when the polishing pad is replaced.

An embodiment of the present disclosure provides a chemical mechanical polishing apparatus including: a polishing table; a polishing pad attachment feature on a surface of the polishing table; a polishing pad supply area outside the polishing table; and a polishing pad carrier configured to move a polishing pad from the polishing pad supply area to the polishing pad attachment feature, wherein the polishing pad attachment feature includes a magnetic feature and/or an adsorption feature to attach the polishing pad to the polishing table. The polishing pad attachment feature may include the magnetic feature.

The polishing pad attachment feature may include the adsorption feature.

The magnetic feature and/or the adsorption feature may be disposed in a dot shape.

The polishing pad attachment feature may include the magnetic feature and the adsorption feature simultaneously.

The magnetic feature may include a plurality of rings each including at least one magnet, and the adsorption feature may include a plurality of rings each including at least one adsorption opening.

Each ring of the magnetic feature may include a plurality of circumferentially spaced apart magnets, each ring of the adsorption feature may include a plurality of circumferentially spaced apart adsorption openings, and the rings of the magnetic feature and the rings of the adsorption feature may be arranged alternately in a radial direction with respect to a center point of the polishing pad attachment feature.

Each ring of the magnetic feature may include a single continuous circumferentially extending magnet, and/or each ring of the adsorption feature may include a single continuous circumferentially extending adsorption opening.

Each ring of the magnetic feature may include a single continuous magnet extending circumferentially, each ring of the adsorption feature may include a single continuous adsorption opening extending circumferentially, and the rings of the magnetic feature and the rings of the adsorption feature may be arranged alternately in a radial direction with respect to a center point of the polishing pad attachment feature.

The chemical mechanical polishing apparatus may further include a magnetic sub pad under the polishing pad.

The polishing pad may include a magnetic material.

The chemical mechanical polishing apparatus may further include a magnetic layer and a sub pad under the polishing pad.

The polishing pad carrier may include a magnetic feature.

The polishing pad carrier may include an adsorption feature.

The polishing pad carrier may have a rod shape or a multi-stage telescopic rod shape.

The polishing pad in the polishing pad supply area may be continuously wound in a roll, and the polishing pad may include a cutting pattern having a predetermined shape.

The cutting pattern may have a broken line shape with predetermined intervals or a circular shape corresponding to the polishing pad.

Another embodiment of the present disclosure provides a chemical mechanical polishing apparatus including: a polishing table including an attachment feature; and a polishing pad carrier configured to remove a first, worn polishing pad from the polishing table and to position a second, replacement polishing pad on the polishing table, wherein the polishing pad attachment feature includes a magnetic feature and/or an adsorption feature to selectively attach and detach the first and second polishing pads to and from the polishing table.

Another embodiment of the present disclosure provides a method of replacing a polishing pad in a chemical mechanical polishing apparatus, the method including: supplying the polishing pad to a polishing table from a polishing pad supply area outside the chemical mechanical polishing apparatus; and cutting the polishing pad supplied to the polishing table, wherein the supplying the polishing pad to the polishing table from the polishing pad supply area outside the chemical mechanical polishing apparatus includes: attaching the polishing pad to a polishing pad carrier by a magnetic or adsorption method

The polishing pad may include a magnetic layer or a magnetic sub pad.

The polishing pad itself may include a magnetic material.

The cutting of the polishing pad supplied to the polishing table may include: cutting the polishing pad by a pulling force using a pattern on the polishing pad, or cutting the polishing pad using a rail-type cutter or a chopping-type cutter.

Yet another embodiment of the present disclosure provides a polishing table in a chemical mechanical polishing apparatus, the polishing table including a polishing pad attaching portion or attachment feature disposed in or on a surface of the polishing table, wherein the polishing pad attaching portion includes a magnetic portion or magnetic feature and/or an adsorption portion or adsorption feature.

The magnetic portion and/or the adsorption portion may have a dot shape or a circular band shape.

According to embodiments of the present disclosure, a polishing apparatus and a method of replacing a polishing pad are capable of reducing replacement variables and reducing process costs when the polishing pad is replaced.

### BRIEF DESCRIPTION OF THE DRAWINGS

FIG. 1 is a schematic diagram illustrating a process of attaching a polishing pad according to an embodiment.

FIG. 2 is a schematic diagram illustrating a process of detaching a polishing pad according to an embodiment.

FIGS. 3A to 3C are schematic diagrams illustrating a structure of a polishing table according to an embodiment.

FIGS. 4 to 6 are plan views each illustrating a polishing table according to an embodiment.

FIGS. 7A to 7D each illustrate a cross-sectional structure of a polishing pad according to an embodiment.

FIGS. 8A and 8B are schematic diagrams illustrating a polishing pad carrier according to an embodiment.

FIGS. 9, 10, 11A, and 11B are examples each illustrating a method of cutting a polishing pad according to an embodiment.

### DETAILED DESCRIPTION

Hereinafter, embodiments of the present disclosure will be described in detail. However, it is to be understood that these are example embodiments, and the present disclosure is not limited thereby, but is defined only by the scope of claims to be set forth hereinbelow.

Referring to the figures, a chemical mechanical polishing apparatus may include a polishing table 101 having an upper surface to which a polishing pad 301 is attached, a polishing head 201 rotating in contact with an upper surface of the polishing pad 301 in a state where a wafer to be polished is mounted thereon, a conditioner 203 for finely cutting a surface of the polishing pad 301 by pressurizing the surface of the polishing pad 301 with a predetermined pressurizing force so that micropores formed in the surface of the polishing pad 301 appear on the surface, and a slurry supply portion or slurry supply 202 for supplying a slurry to the polishing pad 301.

The polishing table 101 may rotate by driving its rotating shaft to rotate, with the polishing pad 301 made of a polytex material in some embodiments, with which the wafer is polished, being attached to the polishing table 101.

The polishing head 201 may include a carrier head disposed on the upper surface of the polishing pad 301 on the polishing table 101 to hold the wafer, and a polishing arm reciprocating at a constant amplitude while driving the carrier head to rotate.

The slurry supply portion 202 may supply a slurry to the polishing pad 301, such that the slurry is transferred to the wafer through micropores formed in the polishing pad 301 to chemically polish the wafer.

The conditioner 203 may finely cut the surface of the polishing pad 301 to prevent numerous fine foam pores, which serve to contain the slurry where an abrasive and a chemical substance are mixed together in the surface of the polishing pad 301, from being clogged, such that the slurry filled in the foam pores of the polishing pad 301 is smoothly supplied to the wafer held by the carrier head.

To this end, the conditioner 203 may hold a conditioning disk to be brought into contact with the polishing pad 301 during a conditioning process with its housing, and a motor and a gearbox may be equipped in the housing to rotate a rotation shaft of the conditioning disk. In addition, in order to pressurize downward the conditioning disk disposed at an end of an arm rotating around the rotation shaft, a pressurizing apparatus such as a cylinder for pressurizing downward the conditioning disk using pneumatic pressure may be installed inside the housing, and the arm extending from the center of rotation to the housing may perform a sweeping motion to finely cut the polishing pad 301 for foam pores over a large area of the polishing pad 301, thereby modifying the surface of the polishing pad 301.

In this case, the polishing pad 301 is worn out and needs to be replaced periodically. Currently, the replacement of the polishing pad 301 is performed by an engineer, and how well the polishing pad 301 is attached varies depending on a skill level of the engineer. In addition, there are problems of replacement time and low efficiency.

In this regard, an embodiment of the present application provides a method and an apparatus for automating the replacement of the polishing pad 301.

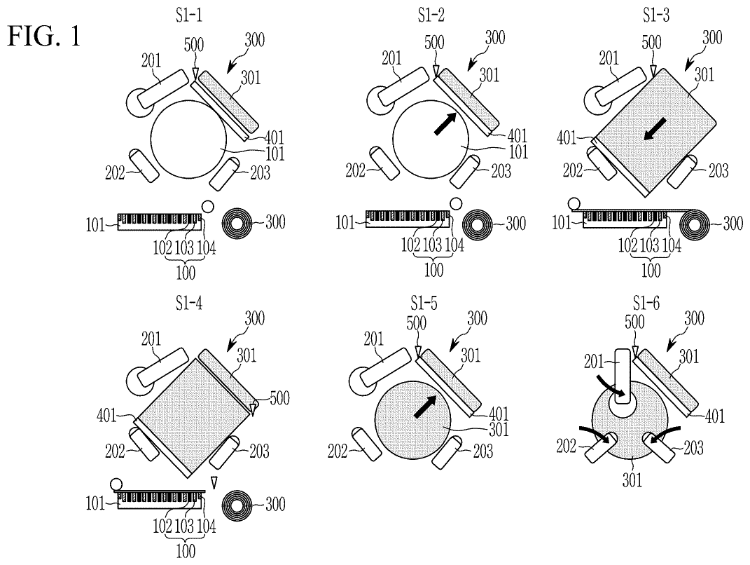

FIG. 1 is a schematic diagram illustrating a process of attaching the polishing pad 301.

As can be seen from FIG. 1, when it is time to replace the polishing pad 301, the polishing head 201, the slurry supply portion 202, and the conditioner 203 move to positions at which it is easy to replace the polishing pad 301 (S1-1).

Then, the polishing pad 301 disposed in a polishing pad supply portion or polishing pad supply area 300 is attached to a polishing pad carrier 401 (S1-2). The polishing pad carrier 401 may move across the polishing table 101 for attaching and detaching the polishing pad 301.

A method of attaching the polishing pad 301 by the polishing pad carrier 401 will be described below.

Then, the polishing pad carrier 401 moves above the polishing table 101 to place the polishing pad 301 on the polishing table 101 (S1-3).

At this time, the polishing table 101 and the polishing pad 301 are attached to each other by a magnetic force and/or adsorption. This attachment method will also be described below.

Next, an unnecessary or excess portion of the polishing pad 301 may be cut out (S1-4). A specific cutting method will also be described below. Thereafter, the polishing pad carrier 401 moves to its initial position (S1-5), and the polishing head 201, the slurry supply portion 202, and the conditioner 203 move back to positions for polishing (S1-6).

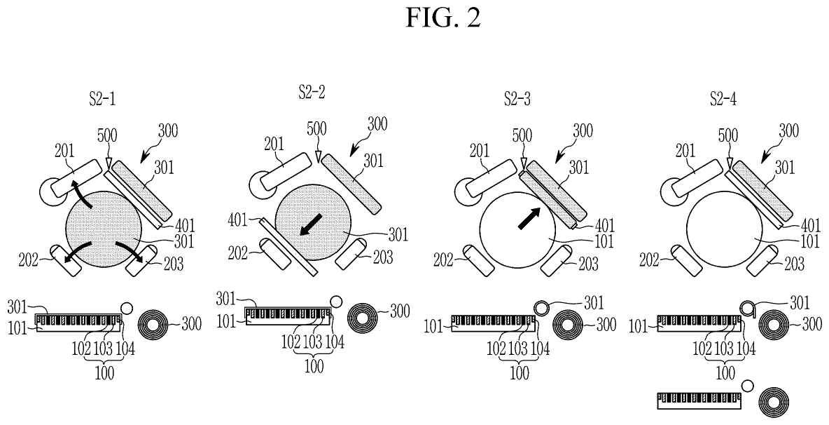

FIG. 2 is a schematic diagram illustrating a process of detaching the attached polishing pad 301.

Similar to the attachment process, first, the polishing head 201, the slurry supply portion 202, and the conditioner 203 move to positions for detaching the polishing pad 301 (S2-1).

Then, the polishing pad carrier 401 is attached to the polishing pad 301 after being moved to an end of the polishing table 101 (S2-2).

At this time, a magnetic force and/or an adsorption force of a polishing pad attaching portion 100 in the polishing table 101 is temporarily eliminated to help detach the polishing pad 301 from the polishing table 101.

The worn-out polishing pad 301 attached to the polishing pad carrier 401 is detached from the polishing table 101 by the movement of the polishing pad carrier 401 (S2-3). Thereafter, the aforementioned process of attaching the polishing pad 301 (S1-1 to S1-6) may be performed again.

More specifically, the device and the process used in each step will be described below.

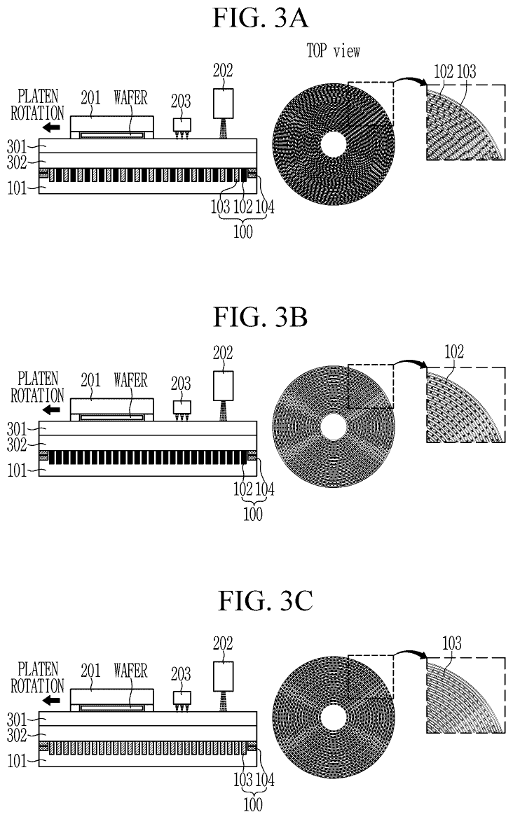

FIG. 3 illustrates a detailed structure of the polishing table 101 for the above-described process.

FIG. 3A is an embodiment in which the polishing pad attaching portion or polishing pad attachment feature 100 disposed on a surface portion of the polishing table 101 includes both a magnetic portion or magnetic feature 102 and an adsorption portion or adsorption feature 103.

A magnetic force in the magnetic portion 102 may be implemented using an electromagnet. Therefore, in the detachment step, the polishing pad 301 can be detached from the polishing table 101 by eliminating the magnetic force.

In addition, the adsorption portion 103 may be implemented in such a manner that pores, holes, channels, or adsorption openings are provided and air is adsorbed by applying a negative pressure to the pores. Whether to attach or detach the polishing pad 301 may be selected depending on whether to adsorb air.

FIG. 3B is an embodiment in which only a magnetic portion 102 exists in the polishing pad attaching portion 100. FIG. 3C is an embodiment in which only an adsorption portion 103 exists in the polishing pad attaching portion 100.

Depending on equipment, the magnetic portion 102 and the adsorption portion 103 may be selectively applied.

A side attaching portion or side attachment feature 104 may be included in each of all the structures of FIGS. 3A to 3C. The side attaching portion 104 may also optionally or simultaneously include a magnetic portion 102 and/or an adsorption portion 103.

The side attaching portion 104 serves to enable an unnecessary or excess area of the cut-out polishing pad 301 to adhere to the polishing table 101.

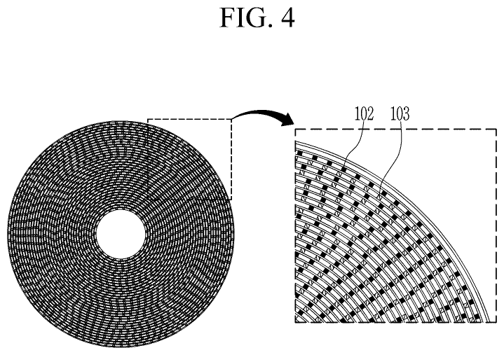

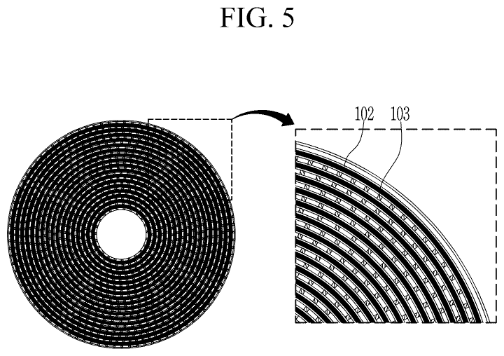

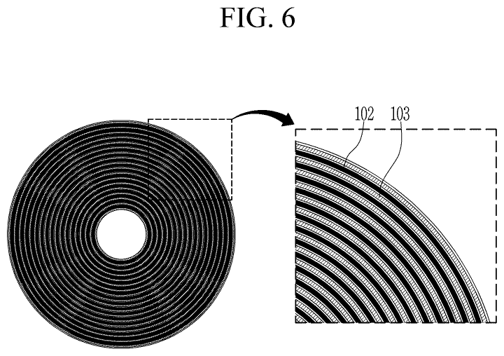

FIGS. 4 to 6 are examples each illustrating what shape and arrangement the magnetic portion 102 and/or the adsorption portion 103 in the polishing pad attaching portion 100 may have.

The magnetic portion 102 and/or the adsorption portion 103 may exist in a dot shape. In other words, the magnetic portion 102 may include a plurality of spaced apart magnets and/or the adsorption portion 103 may include a plurality of spaced apart pores or adsorption openings. At this time, the magnetic portion 102 and the adsorption portion 103 may be provided alternately in a radial direction. The magnetic portion 102 may include a plurality of concentric rings each including a plurality of circumferentially spaced apart magnets. The adsorption portion 103 may include a plurality of concentric rings each including a plurality of circumferentially spaced apart pores or adsorption openings.

Alternatively, at least one of the magnetic portion 102 and the adsorption portion 103 may have a continuous band or ring shape. In other words, each ring of the magnetic portion 102 may include a single continuous circumferentially extending magnet and/or each ring of the adsorption portion 103 may include a single continuous circumferentially extending pore or adsorption opening. At this time, bands may be disposed at predetermined intervals, and the different types of bands may be disposed alternately.

The shape of the magnetic portion 102 and/or the adsorption portion 103 may be appropriately selected to control an adsorption strength implemented according to the specifications of the polishing pad 301.

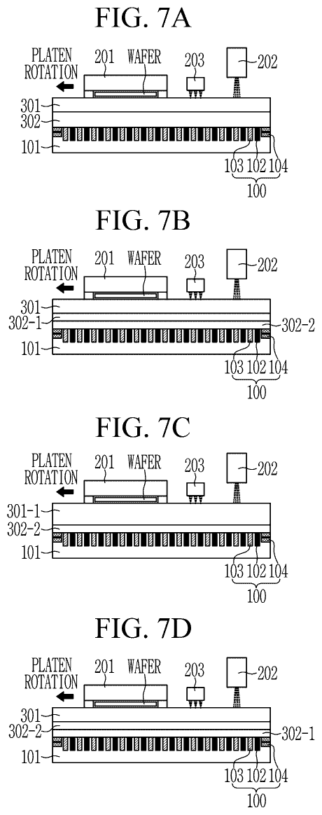

FIG. 7 illustrates examples of structures for the polishing pad 301 according to various embodiments of the present disclosure.

FIG. 7A is an example of a structure including a magnetic sub pad 302 disposed under the polishing pad 301. The magnetic sub pad 302 enables the polishing pad 301 to remain coupled to the magnetic portion 102 in the polishing pad attaching portion 100 described above.

Alternatively, magnetism may be imparted to the polishing pad 301 itself as illustrated in FIG. 7C. A method of imparting magnetism will be described below.

As illustrated in FIGS. 7B and 7D, a structure including a separate magnetic layer 302-1 may be used together with a non-magnetic sub pad 302-2. The positions of these two layers are interchangeable.

As a method of imparting magnetism to each of the above-described layers, the following method may be used.

First, a synthetic material is used so that a magnetic polymer is added to the typical material. The basic material of the polishing pad is based on polyurethane, and the polyurethane-based material may form a composite material with a conductive polymer. That is, this is a method using a magnetic polymer. For example, PANiCNQ (a polymer of polyaniline (PANi) and tetracyanoquinodimethane (TCNQ)) may be used.

As another method, magnetic particles may be mixed with a polymer material. This is a method of preparing a material by dispersing magnetic inorganic particles in a polymer, and for example, particles such as Fe₃O₄ and CoFeO₄ may be used.

As another method, the conductive polymer and the magnetic particles, which are described above, may be simultaneously used. This can be selectively applied according to the required magnetic force.

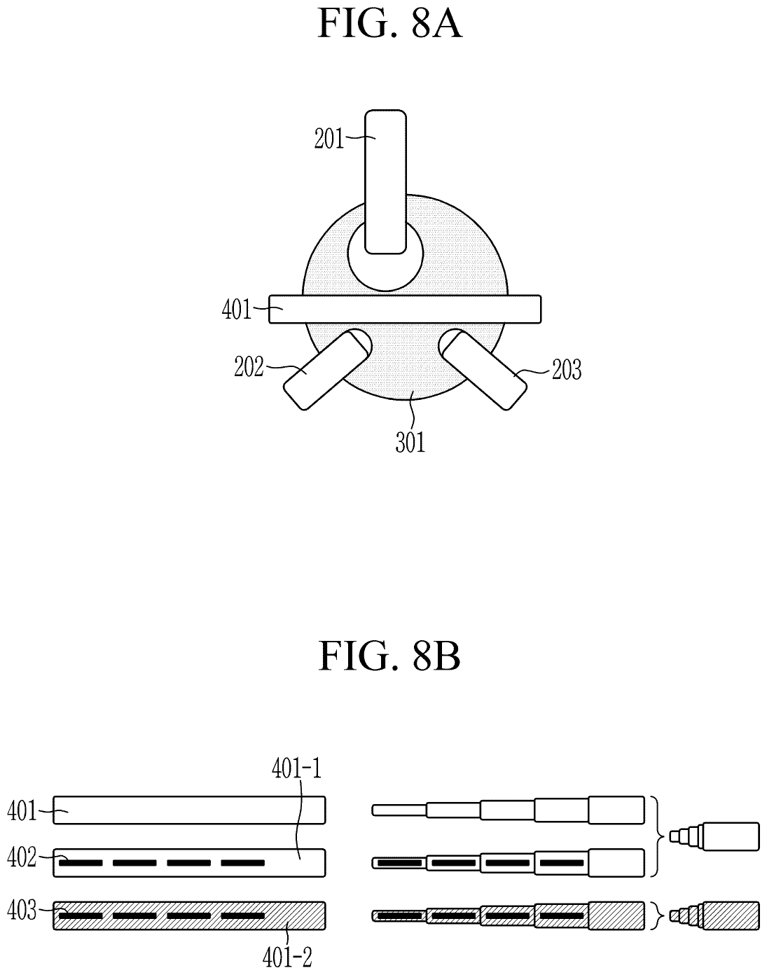

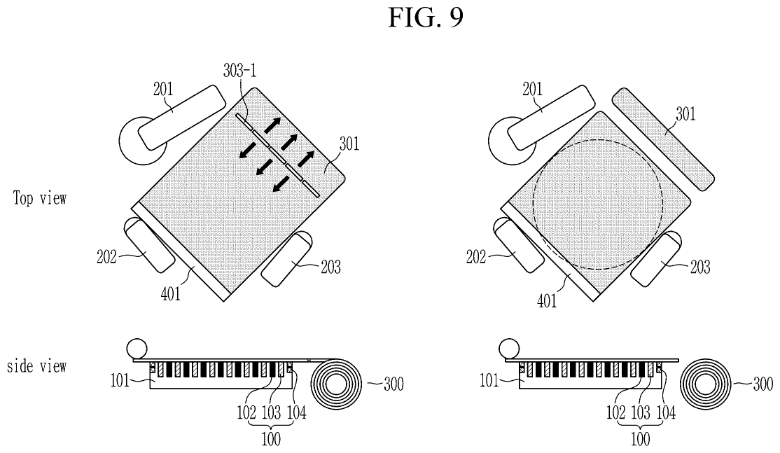

FIG. 8 illustrates an example of the polishing pad carrier 401 described above.

The polishing pad carrier 401 may be attached to the polishing pad 301 using a magnetic or adsorption method.

To this end, the polishing pad carrier 401 itself may include a magnetic portion or magnetic feature 402 and may be a magnetic polishing pad carrier 401-1. At this time, the polishing pad carrier 401 may be implemented by an electromagnet to apply or eliminate a magnetic force.

Additionally or alternatively, an adsorption portion or adsorption feature 403 may be provided inside the polishing pad carrier 401 and may be an adsorption polishing pad carrier 401-2. This is similar to the structure of the polishing table 101 described above, and the polishing pad carrier 401 is also similar to the polishing table 101 in the principle for attaching and detaching the polishing pad 301. It will be appreciated that the polishing pad carrier 401 may include both the magnetic feature 402 and the adsorption feature 403.

The polishing pad carrier 401 needs to be easily moved in the polishing apparatus, and a smaller space occupied by the polishing pad carrier 401 is more helpful in implementing the device. Therefore, the polishing pad carrier 401 may be implemented in a multi-stage rod shape (e.g., telescoping) to remain in a folded structure or retracted state except at the time of attaching or detaching the polishing pad 301 (e.g., in an extended state).

FIGS. 9 to 11 are examples each illustrating a method of cutting the polishing pad according to an embodiment.

In the example of FIG. 9, a cutting pattern previously disposed in the polishing pad 301 may exist. This cutting pattern makes it possible to cut a portion by pulling the corresponding portion. This is similar to the method of cutting roll tissue.

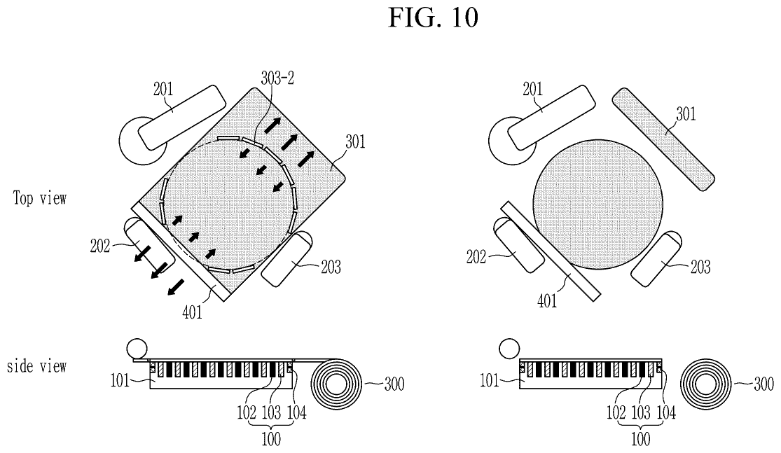

FIG. 10 is an example in which the cutting pattern is a circular broken line pattern 303-2, which has the same shape as the polishing pad 301. When the polishing pad 301 is cut in the circular shape, an unnecessary or excess portion of the polishing pad 301 may remain in a small amount in the process, resulting in a reduction in risk of process defect.

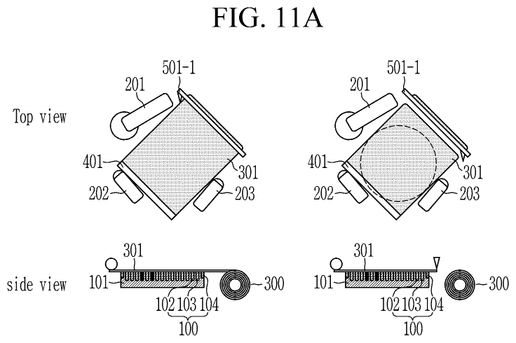

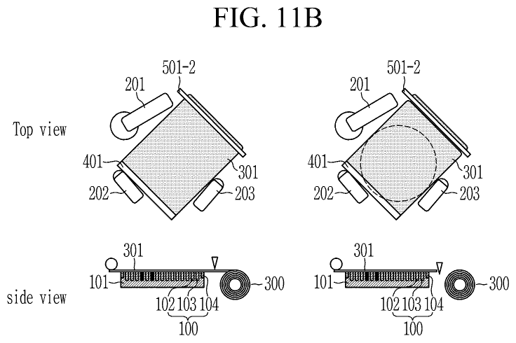

FIG. 11 is an example in which the polishing pad 301 does not have such a cutting pattern, and the polishing pad 301 may be cut using a cutter.

As specific examples, a rail-type cutter 501-1 as illustrated in FIG. 11A may be used, or a chopping-type cutter 501-2 as illustrated in FIG. 11B may be used.

Another embodiment of the present application provides a polishing table in a chemical mechanical polishing apparatus, the polishing table including a polishing pad attaching portion or polishing pad attachment feature 100 disposed in a surface of the polishing table, wherein the polishing pad attaching portion 100 includes a magnetic portion or magnetic feature 102 and/or an adsorption portion or adsorption feature 103. The structure of the polishing table 101 is the same as what has been described above, and thus, the description thereof will be omitted.

Another embodiment of the present application provides a chemical mechanical polishing apparatus including: a polishing table 101; a polishing pad attaching portion or polishing pad attachment feature 100 disposed in a surface of the polishing table; a polishing pad supply portion or area 300 disposed outside the polishing table; and a polishing pad carrier 401 for moving a polishing pad 301 in the polishing pad supply portion to the polishing pad attaching portion, wherein the polishing pad attaching portion includes a magnetic portion or magnetic feature 102 and/or an adsorption portion or adsorption feature 103 to attach the polishing pad 301 to the polishing table 101.

In the polishing apparatus, the polishing pad supply portion 300 may have a form in which the polishing pad 301 is rolled around a central axis. Alternatively, the polishing pad supply portion 300 may have a form in which the polishing pad 301 may be continuously folded. The structure of the polishing pad supply portion 300 is not limited as long as flexible fabric can be continuously supplied.

It is to be understood that the present disclosure is not limited to the above-described embodiments, but may be modified in various different forms, and one having ordinary knowledge in the art to which the present disclosure pertains may embody the present disclosure in other specific forms without departing from the technical idea or essential features of the present disclosure. Therefore, it should be noted that the embodiments described above are exemplary, not restrictive, in all aspects.

What is claimed is:

1. A chemical mechanical polishing apparatus comprising:
a polishing table;
a polishing pad attachment feature on a surface of the polishing table;
a polishing pad supply area outside the polishing table; and
a polishing pad carrier configured to move a polishing pad from the polishing pad supply area to the polishing pad attachment feature,
wherein the polishing pad attachment feature includes a magnetic feature and/or an adsorption feature to attach the polishing pad to the polishing table.

2. The chemical mechanical polishing apparatus of claim 1, wherein
the polishing pad attachment feature includes the magnetic feature.

3. The chemical mechanical polishing apparatus of claim 1, wherein
the polishing pad attachment feature includes the adsorption feature.

4. The chemical mechanical polishing apparatus of claim 1, wherein
the polishing pad attachment feature includes the magnetic feature and the adsorption feature.

5. The chemical mechanical polishing apparatus of claim 4, wherein the magnetic feature comprises a plurality of rings each comprising at least one magnet, and the adsorption feature comprises a plurality of rings each comprising at least one adsorption opening.

6. The chemical mechanical polishing apparatus of claim 5, wherein
each ring of the magnetic feature comprises a plurality of circumferentially spaced apart magnets, each ring of the adsorption feature comprises a plurality of circumferentially spaced apart adsorption openings, and the rings of the magnetic feature and the rings of the adsorption feature are arranged alternately in a radial direction with respect to a center point of the polishing pad attachment feature.

7. The chemical mechanical polishing apparatus of claim 5, wherein
each ring of the magnetic feature comprises a single continuous circumferentially extending magnet, and/or
each ring of the adsorption feature comprises a single continuous circumferentially extending adsorption opening.

8. The chemical mechanical polishing apparatus of claim 7, wherein
each ring of the magnetic feature comprises a single continuous magnet extending circumferentially,
each ring of the adsorption feature comprises a single continuous adsorption opening extending circumferentially,
and the rings of the magnetic feature and the rings of the adsorption feature are arranged alternately in a radial direction with respect to a center point of the polishing pad attachment feature.

9. The chemical mechanical polishing apparatus of claim 1, further comprising:
a magnetic sub pad under the polishing pad.

10. The chemical mechanical polishing apparatus of claim 1, wherein:
the polishing pad comprises a magnetic material.

11. The chemical mechanical polishing apparatus of claim 1, further comprising:
a magnetic layer and a sub pad under the polishing pad.

12. The chemical mechanical polishing apparatus of claim 1, wherein:
the polishing pad carrier comprises a magnetic feature and/or
an adsorption feature.

13. The chemical mechanical polishing apparatus of claim 1, wherein:
the polishing pad carrier has a rod shape or a multi-stage telescopic rod shape.

14. The chemical mechanical polishing apparatus of claim 1, wherein:
the polishing pad in the polishing pad supply area is continuously wound in a roll, and
the polishing pad comprises a cutting pattern having a predetermined shape.

15. The chemical mechanical polishing apparatus of claim 14, wherein:
the cutting pattern has a broken line shape with predetermined intervals or a circular shape corresponding to the polishing pad.

16. A chemical mechanical polishing apparatus comprising:
a polishing table including an attachment feature; and
a polishing pad carrier configured to remove a first, worn polishing pad from the polishing table and to position a second, replacement polishing pad on the polishing table,
wherein the polishing pad attachment feature includes a magnetic feature and/or an adsorption feature to selectively attach and detach the first and second polishing pads to and from the polishing table.

17. A method of replacing a polishing pad in a chemical mechanical polishing apparatus, the method comprising:
supplying the polishing pad to a polishing table from a polishing pad supply area outside the chemical mechanical polishing apparatus; and
cutting the polishing pad supplied to the polishing table,
wherein the supplying the polishing pad to the polishing table from the polishing pad supply area outside the chemical mechanical polishing apparatus comprises:
attaching the polishing pad to a polishing pad carrier by a magnetic or adsorption method.

18. The method of claim 17, wherein:
the polishing pad includes a magnetic layer or a magnetic sub pad.

19. The method of claim 17, wherein:
the polishing pad comprises a magnetic material.

20. The method of claim 17, wherein:
the cutting of the polishing pad supplied to the polishing table comprises:
cutting the polishing pad by a pulling force using a pattern on the polishing pad, or
cutting the polishing pad using a rail-type cutter or a chopping-type cutter.
